(19) United States
(12) Patent Application Publication
(10) Pub. No.: US 2008/0083943 A1
(43) Pub. Date: Apr. 10, 2008

(54) DUAL-GATE MEMORY DEVICE AND OPTIMIZATION OF ELECTRICAL INTERACTION BETWEEN FRONT AND BACK GATES TO ENABLE SCALING

(76) Inventor: Andrew J. Walker, Mountain View, CA (US)

Correspondence Address: MACPHERSON KWOK CHEN & HEID LLP, 2033 GATEWAY PLACE, SUITE 400, SAN JOSE, CA, 95110, US

(21) Appl. No.: 11/749,094

(22) Filed: May 15, 2007

Related U.S. Application Data
(63) Continuation-in-part of application No. 11/548,231, filed on Oct. 10, 2006.

(51) Int. Cl. H01L 29/788; G11C 11/34; H01L 21/336

(52) U.S. Cl. 257/315; 365/185.17; 438/264; 257/E29.3; 257/E21.409

(57) ABSTRACT

A memory circuit having dual-gate memory cells and a method for fabricating such a memory circuit are disclosed. The dual-gate memory cells each include a memory device and an access device sharing a semiconductor layer, with their respective channel regions provided on different surfaces of the semiconductor layer. The semiconductor layer has a thickness such that electrical interaction between the access device and the memory device is characterized by a sensitivity parameter having a value within a predetermined range for a sub-threshold voltage applied to a gate electrode of the access device. To achieve good scalability of the dual-gate memory cells, the semiconductor layer between the memory device gate and access device gate can be thinned. This results in a larger sensitivity parameter but this parameter is still small enough to avoid memory charge disturbs. The dual-gate memory cells can be used as building blocks for a non-volatile memory array, such as a memory array formed by NAND-strings. In such an array, during programming of a nearby memory device in a NAND string, in NAND-strings not to be programmed, if inversion regions are allowed to be formed in the semiconductor layer, or if the semiconductor layer is allowed to electrically float, electrical interaction exists between the access devices and the memory devices to inhibit programming of the memory devices.

### CROSS-REFERENCE TO RELATED APPLICATIONS

The present application is a continuation-in-part application of U.S. patent application Ser. No. 11/548,231 (“the '231 application”), entitled “Dual-Gate Device and Method,” filed on Oct. 10, 2006. In addition, the subject matter of the present patent application is related to (a) U.S. patent application Ser. No. 11/000,114 (“the '114 application”), entitled “Dual-Gate Device and Method,” filed on Nov. 29, 2004, and (b) U.S. patent application Ser. No. 11/197,462 (“the '462 application”), entitled “Dual-Gate Device and Method,” filed on Aug. 3, 2005. The disclosures of the '114, the '462 and the '231 applications are hereby incorporated by reference in their entireties.

### BACKGROUND OF THE INVENTION

1. Field of the Invention

The present invention relates to dual-gate memory devices. In particular, the present invention relates to improving performance of a dual-gate memory device by optimizing the electrical coupling between the front and the back gates.

2. Discussion of the Related Art

Dual-gate devices for non-volatile memory applications have been described in various U.S. patents and patent applications. For example, U.S. Pat. No. 6,054,734 (“Aozasa”), entitled “Non-volatile memory cell having dual gate electrodes,” to Aozasa et al., discloses a dual-gate device that is designed to take advantage of maximum electrical interaction between the memory device and an opposite read device. Electrical interaction refers to the process by which a voltage imposed on one gate electrode of the dual-gate device affects the threshold voltage of the dual-gate device on the opposite face of the channel semiconductor layer. The maximum electrical interaction allows charge stored in the memory device to be read by the read device on the opposite face of the channel silicon.

In Aozasa, the channel silicon thickness is calculated, assuming that the channel semiconductor is fully monocrystalline and that depletion region thicknesses are defined by the dopant concentration in the channel. Aozasa requires that a charge stored in the memory part of the dual-gate memory cell is to be read by the device on the opposite face of the channel semiconductor. To allow this read process, the channel semiconductor is designed to be thin enough to maximize such electrical interaction.

Various copending U.S. patent applications by the inventor of the present application also describe dual-gate non-volatile memory devices. For example, the '114 application discloses a dual-gate structure designed such that there is no electrical interaction between the memory device and the opposite non-memory device (i.e., substantially complete electrical shielding between the two opposite interfaces). In that dual-gate device, the gate of the memory device is used for reading the presence of charge.

The '462 application discloses a dual-gate structure having a predetermined range of non-memory device gate voltages such that, within that range, there is substantially no electrical interaction between the two opposite devices. Outside that range of non-memory device gate voltages, electrical interaction exists between the memory and the access devices. In that dual-gate structure, the gate electrode of the memory device is used to sense the presence of charge, using a read voltage that is within the predetermined range.

The '231 application discloses a dual-gate structure having a constant sensitivity parameter that can be tuned to achieve a predetermined electrical interaction between the opposite gate electrodes. A gate voltage applied to one face of the dual-gate device affects the threshold voltage of the opposite device, as measured on the opposite device. In one measurement, the effect of the access device gate voltage on the memory device's threshold voltage was shown to be a straight line with a negative slope equal to a “sensitivity” parameter.

### SUMMARY

According to one embodiment of the present invention, a memory circuit having dual-gate memory cells and a method for fabricating such a memory circuit are disclosed. The dual-gate memory cells each include a memory device and an access device sharing a semiconductor layer, with their respective channel regions provided on different surfaces of the semiconductor layer. The semiconductor layer has a thickness such that electrical interaction between the access device and the memory device is characterized by a sensitivity parameter having a value within a predetermined range for a sub-threshold voltage applied to a gate electrode of the access device.

The dual-gate memory cells can be used as building blocks for a non-volatile memory array, such as a memory array formed by NAND-strings. In such an array, during programming of a nearby memory device in a NAND string, in NAND-strings not to be programmed, if inversion regions are allowed to be formed in the semiconductor layer, or if the semiconductor layer is allowed to electrically float, electrical interaction exists between the access devices and the memory devices to inhibit programming of the memory devices.

The present invention is better understood upon consideration of the detailed description below in conjunction with the accompanying drawings.

### BRIEF DESCRIPTION OF THE DRAWINGS

FIG. 1 plots the source-drain currents of a memory device in a dual-gate memory device as a function of the voltage on the gate electrode of the memory device, for various voltages at the gate electrode of the access device in the same dual-gate device, according to one embodiment of the present invention.

FIG. 2 plots the threshold voltages of the memory device of FIG. 1, as a function of the voltage on the gate electrode of the access device.

FIGS. 3A-3L show a method applicable to forming a NAND-type non-volatile memory device, according to one embodiment of the present invention.

FIG. 4A shows a symbol representing a dual-gate memory cell of the present invention.

FIG. 4B shows a structural schematic representation of a dual-gate memory cell of the present invention.

FIG. 5A is a circuit diagram showing two NAND strings, each comprising a number of dual-gate memory cells, according to one embodiment of the present invention.

FIG. 5B shows a structural schematic representation of two NAND strings according to one embodiment of the present invention.

FIG. 5C shows the voltage waveforms at various nodes of dual-gate NAND strings 501 and 502 from FIG. 5B, according to one embodiment of the present invention, when one memory cell is programmed illustrating a strong electrical interaction between the memory device and the access devices, provided to inhibit programming.

FIG. 6 shows structure 800, which is formed by stacking dual-gate NAND-type non-volatile memory devices; the stacking is achieved by applying the processing steps shown in FIGS. 3A-3L repetitively, according to one embodiment of the present invention.

FIG. 7 shows structure 900, which is also formed by stacking dual-gate NAND-type non-volatile memory devices, according to one embodiment of the present invention; in structure 900, each memory gate electrode has two gate dielectric layers.

FIG. 8 shows structure 1000, which is also formed by stacking dual-gate NAND-type non-volatile memory devices, according to one embodiment of the present invention; in structure 1000, each access gate electrode has two gate dielectric layers.

FIG. 9 shows a configuration of voltages imposed on the various terminals of a NAND-type memory string formed out of dual-gate devices during a read operation.

FIG. 10 plots the current of a dual-gate memory string (e.g., the NAND-type memory string of FIG. 9) as a function of the voltage on the gate electrode of a memory device being read, for various voltages across the memory string between bitline and source when the dual-gate device is not optimized for scaling.

FIG. 11 plots the current of a dual-gate memory string (e.g., the NAND-type memory string of FIG. 9) as a function of the voltage on the gate electrode of a memory device being read, for various voltages across the memory string between bitline and source when the dual-gate device is optimized for scaling.

### DETAILED DESCRIPTION OF THE PREFERRED EMBODIMENTS

The present invention provides a dual-gate semiconductor memory device having a predetermined electrical interaction relationship between the bottom gate and the front gate. Actual experimental data has been taken on dual-gate memory devices to assess the effect that the gate voltage on one device has on the threshold voltage of the opposite device. In a dual-gate device formed by a memory device and an access device, when the access device is rendered non-conducting (e.g., by applying a suitable voltage to its gate electrode), the electrical interaction between the access device and the memory device may be characterized by a sensitivity parameter, such as discussed in the '231 application.

The present invention provides an optimization approach that allows the dimensions of a dual-gate device to diminish by suitably thinning the channel semiconductor layer. A thinner channel semiconductor layer increases the value of the sensitivity parameter, but provides enhanced device scalability. The greater electrical interaction between the top and bottom devices (i.e., the increased sensitivity parameter) has little impact on NAND-type dual gate memory devices, where charge stored in the memory device is read by examining the threshold voltage of the memory device, instead of the access device on the opposite face of the channel semiconductor layer. The desired electrical interaction may be achieved by controlling, for example, the thickness of the channel semiconductor layer. For example, increased electrical interaction by thinning the channel semiconductor layer may improve punchthrough characteristics of the dual-gate device. As the devices shrink in more advanced technology generations, the ability to control punchthrough characteristics becomes even more critical.

The dual-gate semiconductor memory device is suitable for use in three-dimensionally stacked memory circuits to achieve high circuit density. Additionally, when used in a NAND-type non-volatile semiconductor memory device, a memory device of the present invention experiences only minor disturbs of stored electric charge during programming and reading.

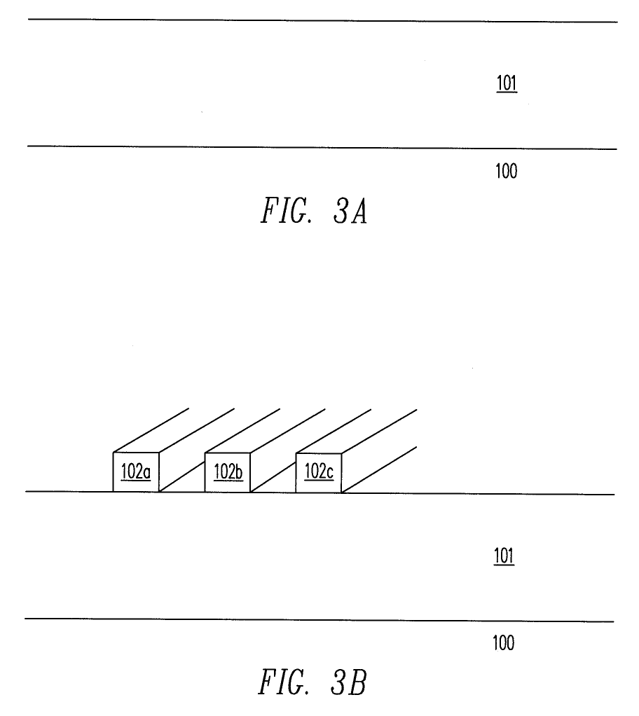

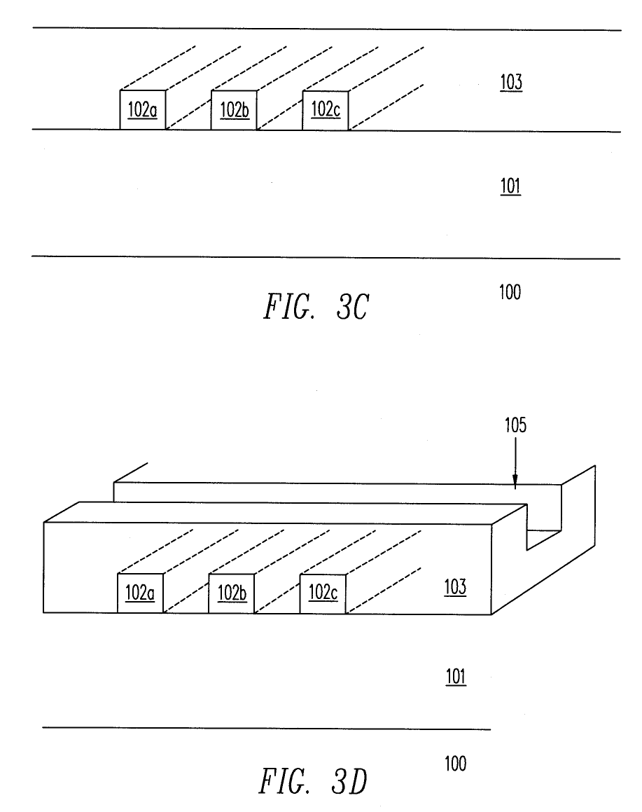

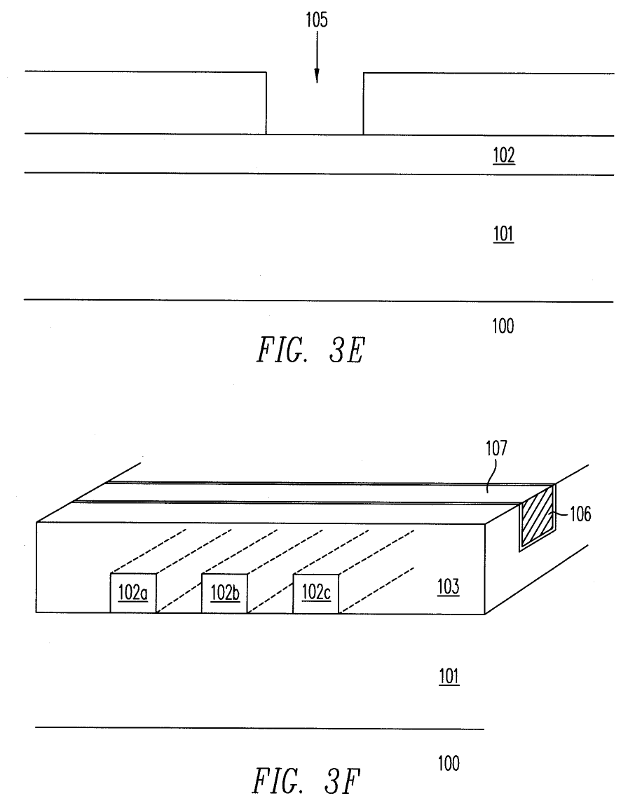

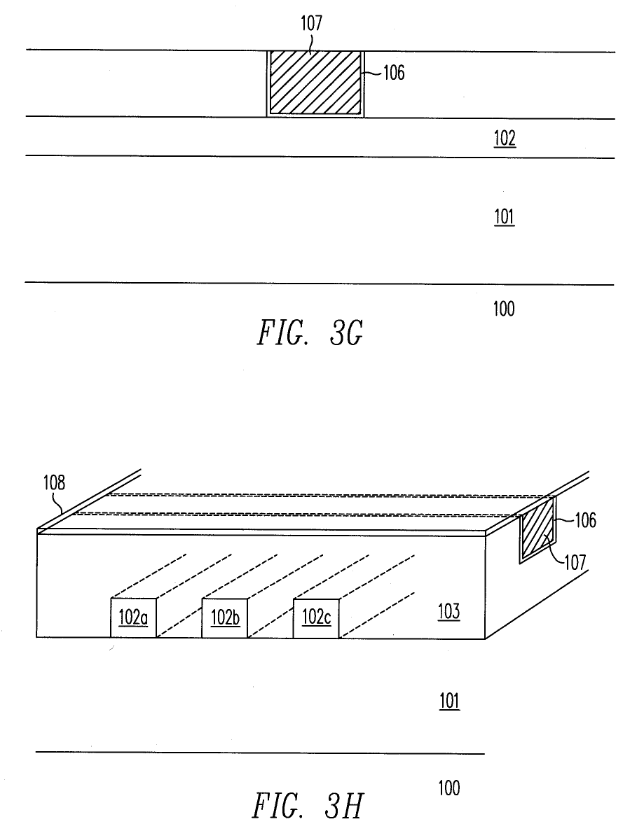

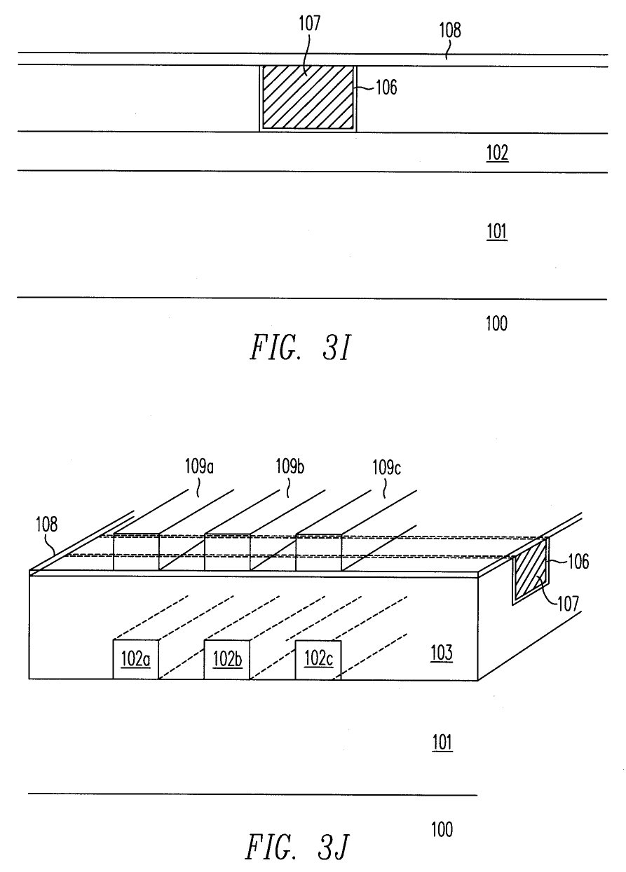

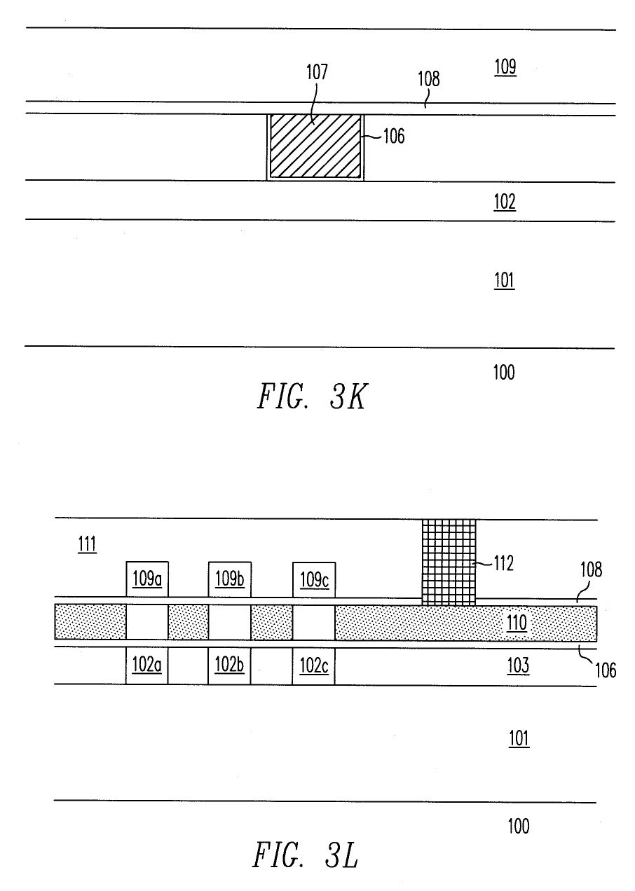

FIGS. 3A-3L illustrate a method suitable for forming a NAND-type non-volatile semiconductor memory device, according to one embodiment of the present invention.

FIG. 3A shows insulating layer 101 provided on substrate 100. Substrate 100 may be a semiconductor wafer containing integrated circuitry for controlling a non-volatile memory. The semiconductor wafer may be either of a bulk type, where the substrate is made of a single crystal of semiconductor, such as silicon, or of a semiconductor-on-insulator type, such as silicon on insulator (SOI), where the integrated circuitry is made in the thin top silicon layer. Insulating layer may be planarized using conventional chemical mechanical polishing (CMP). Within insulating layer 101 may be embedded vertical interconnections (not shown in FIG. 3) for connecting the integrated circuitry with the non-volatile memory device. Such interconnections may be made using conventional photolithographic and etch techniques to create contact holes, followed by filling the contact holes with a suitable type of conductor, such as a combination of titanium nitride (TiN) and tungsten (W), or a heavily doped polysilicon.

Next, a conducting material 102 is provided on top of insulating layer 101 using conventional deposition techniques. Material 102 may also comprise a stack of two or more conducting materials formed in succession. Suitable materials for material 102 include heavily doped polysilicon, titanium disilicide (TiSi₂), tungsten (W), tungsten nitride (WN), cobalt silicide (CoSi₂), nickel silicide (NiSi) or combinations of these materials. Conventional photolithographic and etch techniques are used to pattern gate electrode word lines 102a, 102b and 102c, as shown in FIG. 3B. These word lines form the gate electrode word lines for the access devices to be formed, according to one embodiment of the present invention.

Next, an insulating layer 103 is provided over word lines 102a, 102b and 102c. Insulating layer 103 may be provided using high density plasma (HDP), chemical vapor deposition (CVD), plasma enhanced CVD (PECVD), physical vapor deposition (PVD) or may be a spin on glass (SOG). The surface is then planarized using a conventional CMP step, which either may polish insulating layer 103 down to the surface of the word lines 102a, 102b and 102c, or timed such that a controlled thickness remains of insulating layer 103 between the surface of the word lines 102a, 102b and 102c and the top polished surface of insulating layer 103. In the former case, after CMP, a controlled thickness of an insulating material is deposited using one of the techniques discussed above. Under either approach, the result is shown in FIG. 3C.

Next, trenches 105 are etched into insulating layer 103 using conventional photolithographic and etch techniques. The etching exposes at least the surface of the word lines 102a, 102b and 102c and removes a portion of insulating layer 103. Over-etching may also take place, so long as no detriment is made to the electrical working of the eventual completed structure. FIG. 3D shows trench 105 after formation. The trenches are formed in a direction perpendicular to word lines 102a, 102b and 102c. FIG. 3E shows a cross section through both trench 105 and word line 102, which runs along the plane of FIG. 3E. Trench 105 may be 50 Å to 3000 Å thick, preferably about 500 Å. Trenches 105 may be formed in a trench etch which also removes a portion of each word line 102. Such an etch may be achieved by over-etching (using plasma etching, for example) of insulating material 105 into a portion of word lines 102. Thus, the bottom of trench 105 may be situated below the top surface of each word line 102.

Next, thin dielectric layer 106 is formed on top of the structure shown in FIG. 3E. Thin dielectric layer 106 forms the gate dielectric of the access device and may be formed using a conventional method, such as thermal oxidation in an oxidizing ambient, low pressure CVD (LPCVD) deposition of a dielectric material, such as silicon dioxide, silicon nitride, silicon oxynitride, high temperature oxide (HTO), PECVD dielectric (e.g., silicon oxide or silicon nitride), atomic layer deposition (ALD) of silicon oxide, or some high-k dielectric material. The effective oxide thickness may be in the range of 10 Å and 400 Å.

Next, active semiconductor layer 107 is formed by depositing a semiconductor material, such as polycrystalline silicon (polysilicon), polycrystalline germanium, amorphous silicon, amorphous germanium or a combination of silicon and germanium, using conventional techniques such as LPCVD or PECVD. Polycrystalline material may be deposited as a first step as an amorphous material. The amorphous material may then be crystallized using heat treatment or laser irradiation. The material is formed sufficiently thick, so as to completely fill trench 105 (e.g., at least half the width of trench 105). After deposition, the part of the semiconductor material above trench 105 is removed using, for example, either CMP, or plasma etching. Using either technique, the semiconductor material can be removed with very high selectivity relative to insulating layer 103. For example, CMP of polysilicon can be achieved with selectivity with respect to silicon oxide of several hundred to one. The representative result using either technique is shown in FIG. 3F.

FIG. 3G shows a cross section made through trench 105 and word line 102. Word line 102 runs in a direction parallel to the cross section plane of FIG. 3G. Thin dielectric layer 106 forms the gate dielectric layer of the access device and material 107 is the semiconductor material remaining in trench 105 after the material is substantially removed from the surface of insulating layer 103. Material 107 forms the active semiconductor layer for both the memory device and the access device of the dual-gate device. Material 107 may be undoped or may be doped using conventional methods, such as ion implantation, or in-situ doping carried out in conjunction with material deposition. A suitable doping concentration is between zero (i.e., undoped) and 5×10¹⁸/cm³, and may be p-type for an NMOS implementation or n-type for a PMOS implementation. For the NMOS implementation, an n-type dopant may be introduced into material 107 to achieve a negative threshold voltage of the unprogrammed dual-gate memory devices. The thickness of material 107 is selected such that the sensitivity parameter is less than a predetermined value (e.g., 0.8).

Next, dielectric layer 108 is provided, as shown in FIG. 3H. Dielectric layer 108, which is the dielectric layer for the memory device in the dual-gate device, may be a composite ONO layer consisting of a bottom 10 Å to 80 Å thick thin silicon oxide, an intermediate 20 Å to 200 Å silicon nitride layer, and a top 20 Å to 100 Å silicon oxide layer. (Other materials may take the place of the silicon nitride layer, such as silicon oxynitride, silicon-rich silicon nitride, or a silicon nitride layer that has spatial variations in silicon and oxygen content.) Conventional techniques may be used to form these layers. The bottom thin silicon oxide layer may be formed using thermal oxidation in an oxidizing ambient, low pressure oxidation in a steam ambient, or LPCVD techniques that deposits a thin layer of silicon oxide, such as high temperature oxide (HTO). Atomic layer deposition (ALD) may also be used to form the bottom thin silicon oxide layer. The intermediate layer may be formed using LPCVD techniques or PECVD techniques. The top silicon oxide layer may be formed using, for example, LPCVD techniques, such as HTO, or by depositing a thin amorphous silicon layer, followed by a silicon oxidation in an oxidizing ambient.

Alternatively, dielectric layer 108 may be a composite layer consisting of silicon oxide, silicon nitride, silicon oxide, silicon nitride and silicon oxide (ONONO), using the techniques discussed above. As discussed above, the silicon nitride may be replaced by silicon oxynitride, silicon-rich silicon nitride, or a silicon nitride layer that has spatial variations in silicon and oxygen content. Alternatively, an ONONONO layer may be used. Such multiplayer composites may be tailored such that the electric charge stored within dielectric layer 108 persists for longer periods.

Alternatively, dielectric layer 108 may contain a floating gate conductor for charge storage that is electrically isolated from both the gate electrode of the memory device to be formed and the active semiconductor layer. The floating gate conductor may comprise nano-crystals that are placed between the gate electrode and the active semiconductor layer 107. Suitable conductors may be silicon, germanium, tungsten, or tungsten nitride.

Alternatively to charge storage in dielectric layer 108, the threshold voltage shifts may also be achieved by embedding a ferroelectric material whose electric polarization vector can be aligned to a predetermined direction by applying a suitable electric field.

Alternatively, dielectric layer 108 may be a composite layer of silicon oxide, silicon nitride or oxynitride and a high-k (high dielectric constant) dielectric such as aluminum oxide.

FIG. 3I shows a cross section of the forming dual-gate structure through word line 102, after the step forming dielectric layer 108.

Next, conducting material 109 is provided over dielectric layer 108 using conventional deposition techniques. Conducting material 109 may comprise a stack of two or more conducting materials. Suitable materials for conducting material 109 include heavily doped polysilicon, titanium disilicide (TiSi₂), tungsten (W), tungsten nitride (WN), cobalt silicide (CoSi₂), nickel silicide (NiSi), tantalum nitride (TaN) or combinations of these materials. Conventional photolithographic and etch techniques are used to form gate electrode word lines 109a, 109b and 109c, as is shown in FIG. 3J. These word lines form the gate electrode word lines of the forming memory devices, and run substantially parallel to the underlying access gate electrode word lines 102a, 102b and 102c. FIG. 3K shows a cross section through word lines 102 and 109, after the step forming word lines 109a, 109b and 109c.

Next, source and drain regions are formed within active semiconductor layer 107 using conventional methods such as ion implantation. For an NMOS implementation, n-type ions may be implanted with a dose between 1×10¹³/cm² and 1×10¹⁶/cm², using ionic species such as arsenic, phosphorus or antimony. For a PMOS implementation, p-type ions may be implanted at substantially the same dose range. P-type ionic species may include boron, boron difluoride, gallium or indium. The ion implantation provides source and drain regions that are self-aligned to the gate electrode word lines 109a, 109b and 109c. The result is illustrated in FIG. 3L in which regions 110 represent the heavily doped source and drain regions. In one embodiment, these source and drain regions extend from the top surface of active semiconductor layer 107 to its bottom surface. The source and drain regions may be formed using a combination of ion implantation and subsequent thermal steps to diffuse the dopant atoms introduced.

Next, insulating layer 111 may be provided using high density plasma (HDP), CVD, PECVD, PVD or a spin on glass (SOG). The surface may then be planarized using a conventional CMP step. The result is shown in FIG. 3L.

Vertical interconnections 112 may then be formed using conventional photolithographic and plasma etching techniques to form small holes down to gate electrodes 109a, 109b 109c, heavily doped semiconductor active regions 110 and gate electrodes 102a, 102b and 102c. The resulting holes are filled with a conductor using conventional methods, such as tungsten deposition (after an adhesion layer of titanium nitride has been formed) and CMP, or heavily doped polysilicon, followed by plasma etch back or CMP. The result is shown in FIG. 3L.

Subsequent steps may be carried out to further interconnect the dual-gate devices with other dual-gate devices in the same layer or in different layers and with the circuitry formed in the substrate 100.

Although FIG. 3 illustrates a method which forms the access device (i.e., the non-memory device) before forming the memory device, by making dielectric layer 108 charge-storing and dielectric layer 106 non-charge storing, the memory device may be formed before the non-memory device. Irrespective of which order is chosen, the operations of the memory device and non-memory device are substantially the same.

FIG. 3 therefore illustrates forming a dual-gate memory device with access gate 102, access gate dielectric 106, semiconductor active region 107, memory dielectric 108, memory gate electrode 109 and source and drain regions 110.

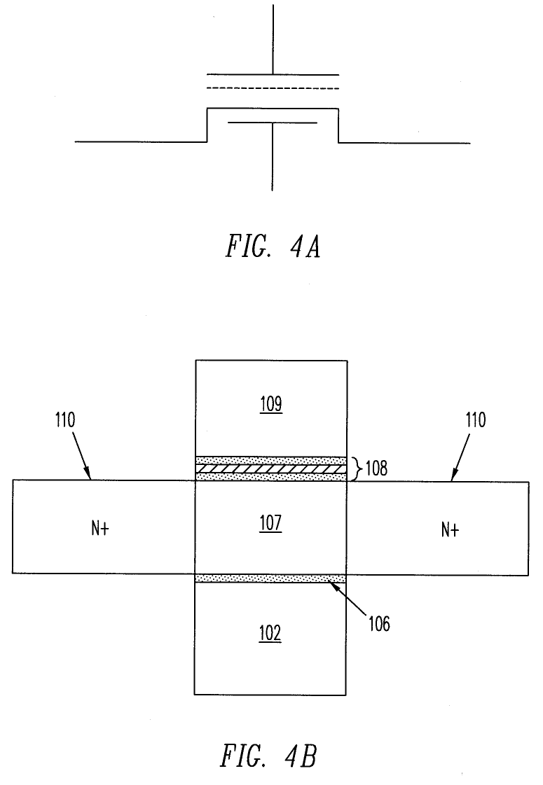

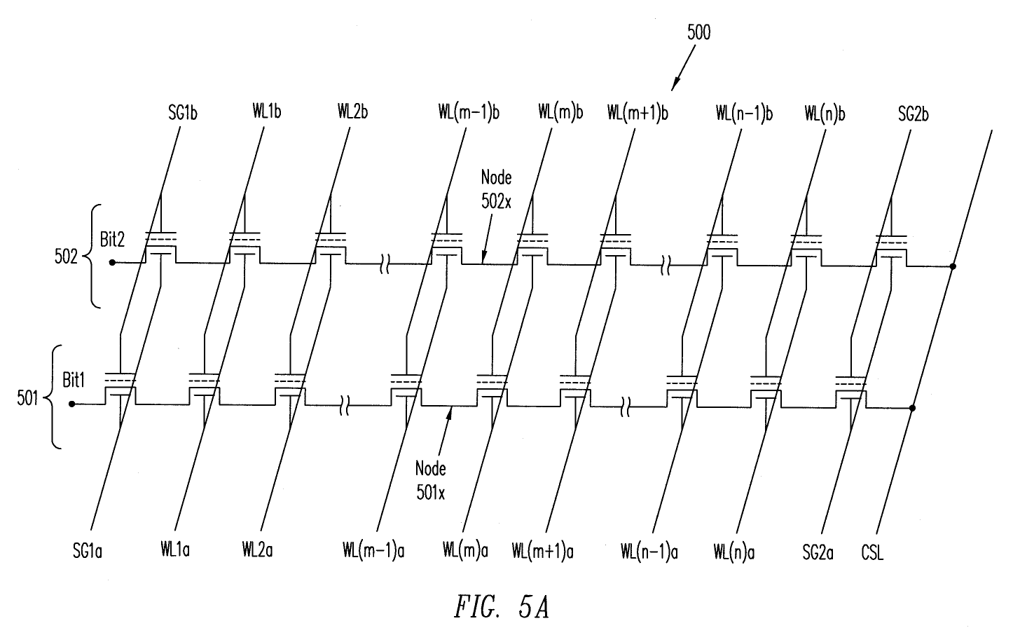

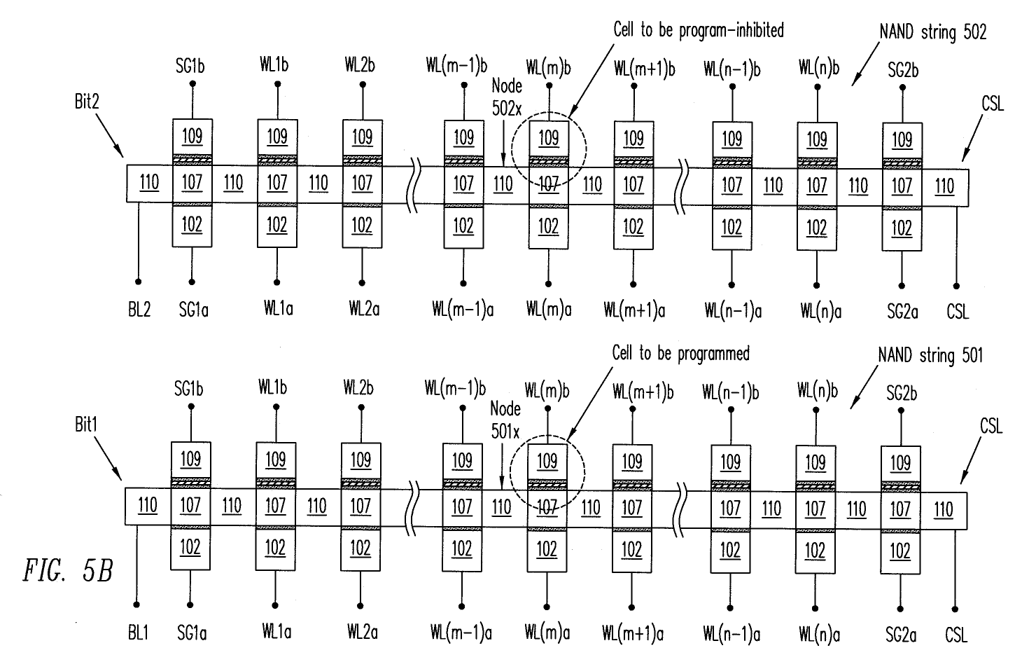

FIG. 4A shows an electric schematic symbol for this dual-gate device. FIG. 4B shows a structural schematic representation of a dual-gate memory cell implemented using a NMOS method, according to one embodiment of the present invention.

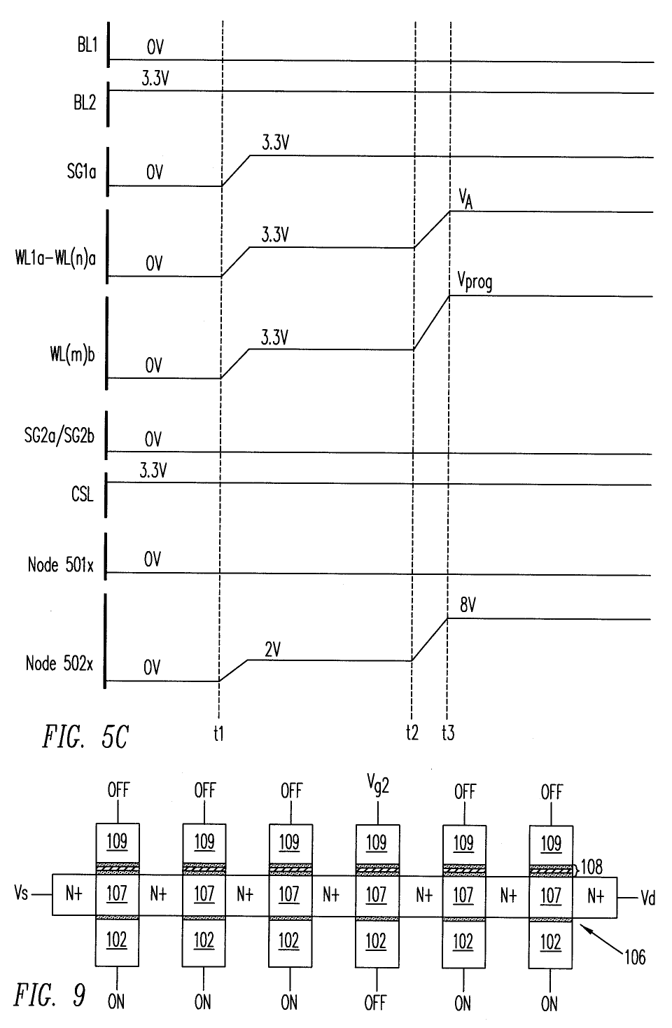

FIG. 5A shows NAND strings 501 and 502, using the electric circuit symbol of FIG. 4A for each dual-gate device. As shown in FIG. 5A, NAND strings 501 and 502 are each formed by a number of dual-gate memory cells, with corresponding dual-gate memory cells from NAND strings 501 and 502 sharing the same access gate electrode word lines and memory gate electrode word lines. NAND strings sharing word lines may be placed adjacent to each other, or may be separated from each other by one or more parallel NAND strings in between. Each NAND string may have one or more select dual-gate devices (e.g., the devices controlled by word lines SG1a and SG1b) in the NAND string between the bit line contact and the dual-gate memory cells, and one or more select dual-gate devices (e.g., the devices controlled by word lines SG2a and SG2b) between the source contact and the dual-gate memory cells.

FIG. 5B shows a structural schematic representation of two NAND strings, according to one embodiment of the present invention. FIG. 5C illustrates NAND string 502 being inhibited from programming, when another NAND string which shares with it the same gate electrode word lines is being programmed. This can be seen by monitoring the voltage on node 502x as shown in FIG. 5C along with the voltage waveforms of all other important nodes during programming of a cell in string 501. Node 502x rises in voltage causing the voltage across the memory dielectric of the cell with memory wordline WL(m)b to be minimized and thus inhibiting programming. Electrical operations of these NAND strings for programming, reading and erasing are described below, so as to explain the electrical interaction required between the access devices and the memory devices in each NAND string.

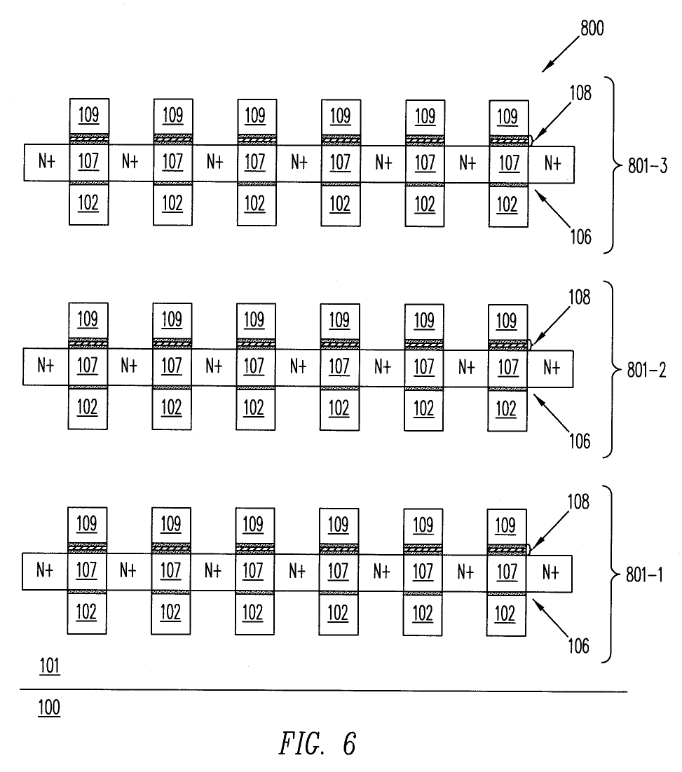

FIG. 6 shows structure 800, which includes multiple layers of dual-gate memory cells, formed using the method steps discussed above in conjunction with FIG. 3. As shown in FIG. 6, layers 801-1, 801-2 and 801-3 may be each formed using the processing sequence illustrated by FIG. 3.

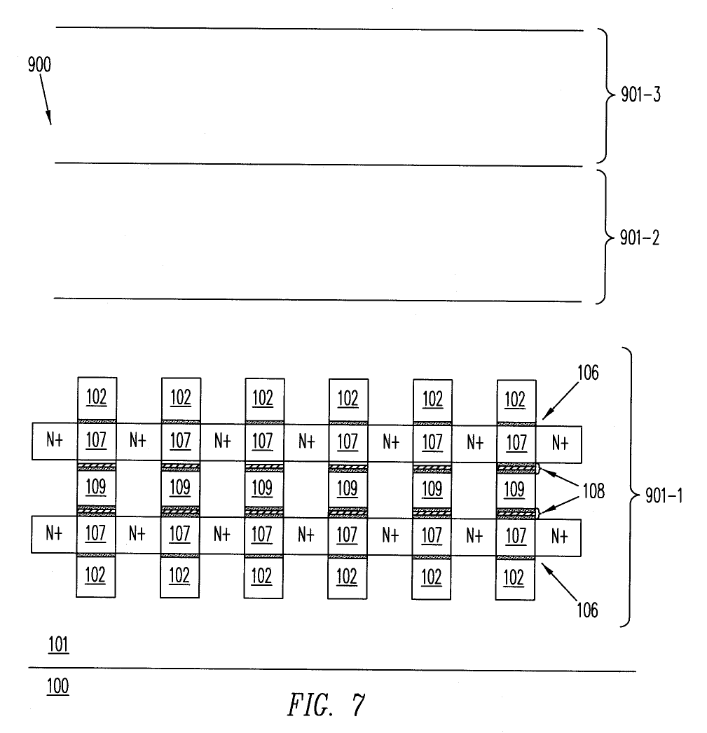

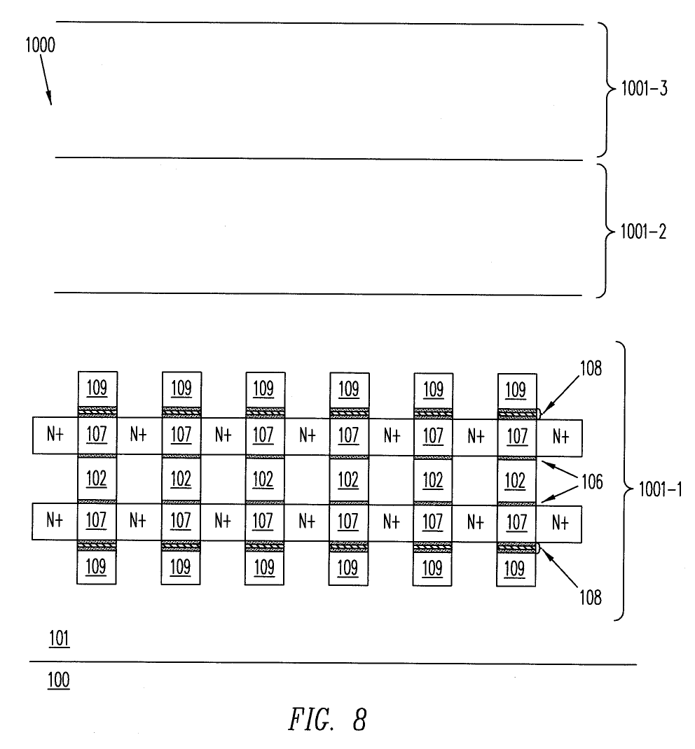

FIG. 7 shows structure 900, also including multiple layers of dual gate memory cells. In structure 900, however, each memory gate electrode serves two distinct devices. FIG. 8 shows structure 1000, which is another alternative structure allowing multiple layers of dual gate memory cells. In structure 1000, each access gate electrode serves two distinct devices. Structures 900 and 1000 may be formed by appropriately modifying the relevant processing sequence discussed above and shown in FIG. 3.

Returning to FIG. 5A, consider the case in which one memory device in NAND string 501 is programmed. NAND string 501 has a bit line contact “Bit1” and a source connected to the common source line “CSL”. Suppose the dual-gate memory cell to be programmed is the one having WL(m)b as the memory gate electrode word line and WL(m)a as the access gate electrode word line. To program this memory cell, a ground voltage or a small voltage is applied to bit line contact “Bit1,” and the source CSL may either be allowed to electrically float or be applied a positive voltage between zero and 10 volts The select gate electrode SG1a is applied a positive select gate program pass voltage between 1 volt and 13 volts. A typical voltage is 7 volts, with the optimal voltage being determined through experimentation. Word line SG1b may also be applied this voltage, a small voltage or may be left to electrically float. The access gate electrode word lines, WL1a to WL(m−1)a, are each applied a positive program pass voltage between 1 volt and 12 volts, with a typical voltage of 7 volts. Again, an optimal voltage value may be determined through experimentation. All other access gate electrode word lines WL(m)a to WL(n)a may be left floating or may be applied a positive voltage between 1 volt and 12 volts, with a typical voltage of 7 volts. The select gate electrode wordlines SG2a and SG2b remain off. A programming voltage between 9V and 18V (typically, 15V) is applied to the word line WL(m)b. Again, an optimum value is determined through experimentation. All other memory cell word lines, WL1b to WL(m−1)b, can be either applied a small voltage or be allowed to electrically float. In this way, a charge inversion layer is formed in the active semiconductor layer (e.g., active semiconductor layer 107) close to the gate electrode of the memory device being programmed. In addition, this inversion channel is tied close to the voltage that is applied to bit line contact “Bit1” during the programming operation, by connecting the inversion channel to bit line contact “Bit1” through the inversion channels and sources and drains regions of all the access devices and active select devices between the bit line contact “Bit1” and the inversion channel of the memory device being programmed. Programming is achieved by tunneling electric charge from the inversion channel of the memory device being programmed to the charge trapping sites within the memory device's gate dielectric layer (such as dielectric layer 108 of FIG. 3).

To reduce “program pass disturb” on memory cells within the same NAND string that has a memory cell being programmed, the program pass voltage is set at a voltage level that preferably has minimal effect on the charge stored in the memory devices of the NAND string between the bit line contact and the memory cell being programmed. The allowable program pass voltages may be determined experimentally (e.g., by taking a dual-gate memory device and confirming that applying the program pass voltages under consideration to the access gate electrode does not materially affect the threshold voltage of its associated memory device after application of the program pass voltage). Typically, even access gate voltages of 9 volts for a thousand seconds have little effect on the threshold voltage of the associated memory device.

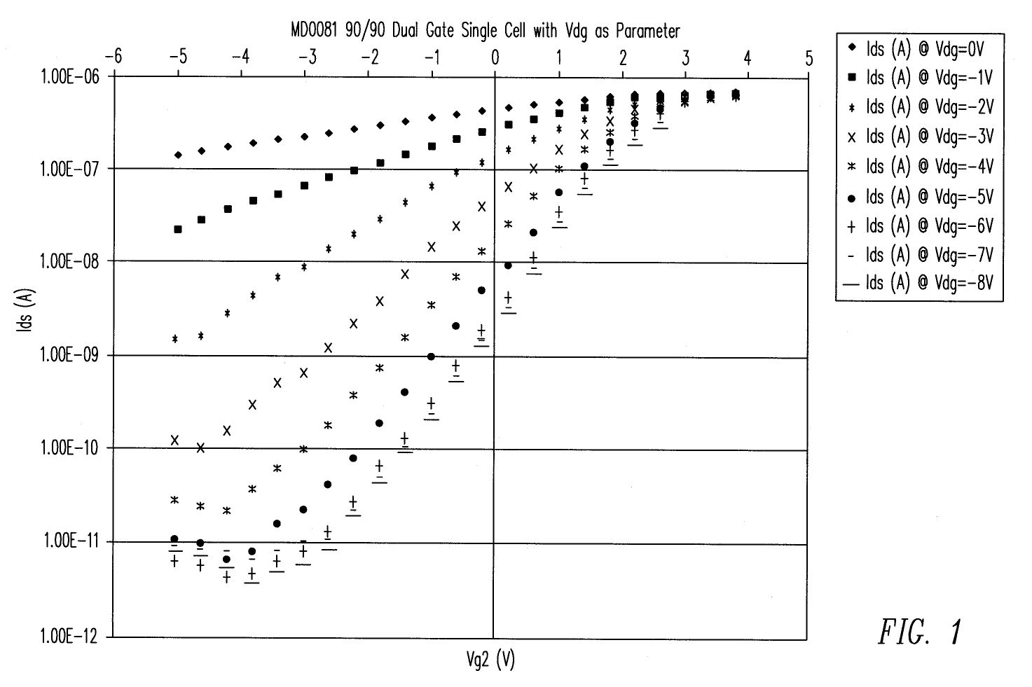

FIG. 1 shows a family of curves each plotting the source-drain current of a memory device in a dual-gate memory device as a function of the voltage on the gate electrode of the memory device. Each member of the family of curves corresponds to a voltage between 0 to −8 volts at the gate electrode of the access device in the same dual-gate device. The curves of FIG. 1 are measured on a dual-gate device having a 60 nm channel length, according to one embodiment of the present invention. As shown in FIG. 1, as the imposed voltage on the gate electrode of the access device increases (i.e., becoming less negative), the access device begins to turn on. The threshold voltage of the memory device, which is defined as the voltage V_{g2} on the gate electrode of the memory device that results in a predetermined source-drain current, then decreases as the access gate voltage becomes less negative.

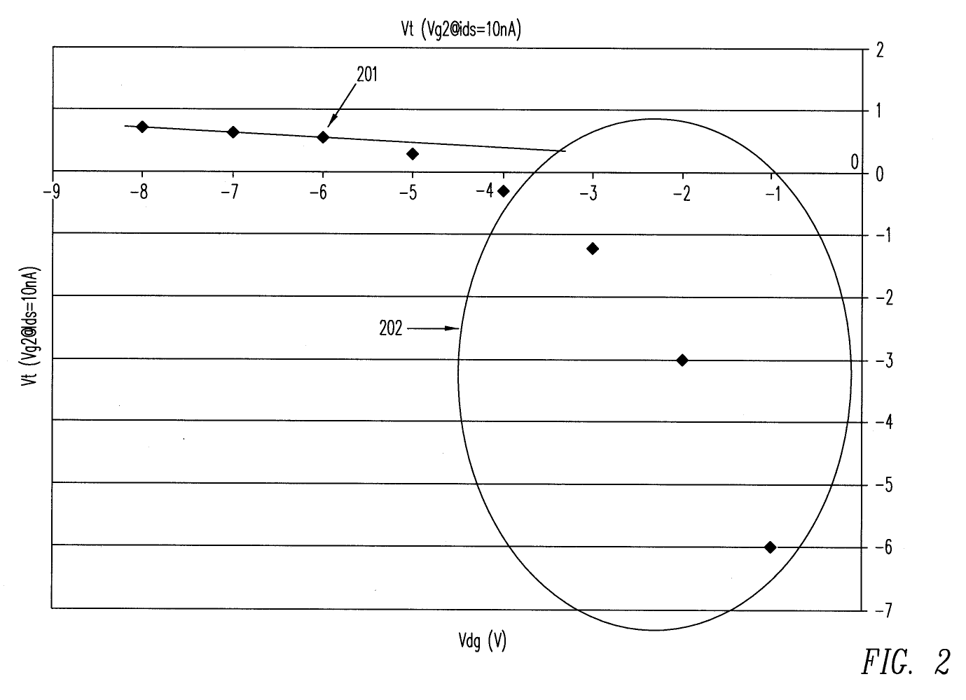

FIG. 2 shows the threshold voltages for the memory device (i.e., the voltage on the gate electrode of the memory device which results in a fixed source-drain current) as a function of the various voltages imposed on the gate electrode of the access device. As shown in FIG. 2, in region 201 (i.e., access device gate voltages between −8 volts to about −4 volts in this particular case, the sensitivity parameter (i.e., the change in memory device threshold voltage per unit change in access device voltage, represented by the magnitude of the slope of the graph within region 201) is about 0.1. Within region 202 (i.e., corresponding to a range of access device gate electrode voltage between −4 volts to −1 volts in this particular case), the access device begins to turn on. As explained in the '231 application, the sensitivity parameter typically increases with decreasing thickness of the channel semiconductor layer in region 201.

To inhibit programming of a memory device in an adjacent NAND string that shares the same word line with a memory device being programmed (e.g. in FIGS. 5A and 5C, inhibiting programming in NAND string 502, while NAND string 501 is being programmed), there are two main approaches. First, the inversion channel formed in NAND string 502 (the inhibited NAND string) is allowed to electrically float. Alternatively, the active semiconductor layer common to the memory devices in NAND string 502 may be allowed to electrically float. Under either method, a resulting strong electrical interaction between the access devices and the memory devices in NAND string 502 exists that reduces the electric field across gate dielectric 108 in the memory device, hence inhibiting programming. Consequently, a much reduced electric charge tunneling occurs between the inhibited memory device's gate electrode and the active semiconductor layer. A further technique for inhibiting programming in NAND string 502 ties the bit line contact “Bit2” (FIG. 5A) to a voltage between 5 volts to 15 volts (typically, 9 volts). An optimal value for this voltage applied on the bit line contact can be determined experimentally.

FIGS. 5A and 5C illustrate allowing the inversion channel formed in inhibited NAND string 502 to electrically float. The voltages applied to NAND string 501 during the programming operation have already been discussed above. During programming, a voltage close to the voltage applied to word line SG1a is applied to bit line contact “Bit2” in NAND string 502. Thus, node 502x in FIG. 5A is allowed to reach a voltage slightly lower than that applied to bit line contact “Bit2”. When the program pass voltage is applied to each of the access gate electrode word lines WL1a through to WL(m−1)a (the rest of the access gate electrodes up to WL(n)a may also have the program pass voltage applied to increase the voltage boost experienced by node 502x as shown in FIG. 5C), an inversion layer is allowed to form in all associated access devices in NAND string 502. Applying the programming voltage to word line WL(m)b also forms an inversion channel in the memory device of the dual-gate device in inhibited string 502. In this way, this inversion channel is connected through other inversion channels and source and drains to node 502x. Because of the strong capacitive coupling between the access gate electrode word lines, on one hand, and the inversion channels and the source and drains regions, on the other hand, node 502x and all the connected inversion channels and the sources and drains regions rise in voltage and electrically float independent of the voltage applied to bit line contact Bit2. During programming, common source line “CSL” of the NAND strings may either be allowed to electrically float or may be tied to a positive voltage between zero volts and 10 volts. This strong electrical interaction between the access devices and the memory devices inhibits programming of the memory cell in NAND string 502 that has its memory gate electrode word line WL(m)b. This can be seen in FIG. 5C showing node 502x rising in voltage and thus limiting the voltage drop across the memory dielectric of the memory device with wordline WL(m)b.

Inhibiting programming in NAND string 502 can also be achieved by electrically floating bit line contact “Bit2” during programming. In this way, little or no inversion occurs in any dual-gate device within the active semiconductor layer of NAND string 502, thus further allowing the active semiconductor layer (e.g., active semiconductor layer 107) to electrically float. Consequently, capacitive coupling results between the access devices and the memory devices within this NAND string 502. This capacitive coupling results in the necessary program inhibition in the memory cell in NAND string 502 that has WL(m)b as its memory device gate electrode. Under this method, select dual-gate devices with word lines SG1a and SG1b, may not be necessary for the operation of the NAND memory device, thus further increasing the memory density achievable.

In summary, during programming, program pass disturb immunity in the memory cells of NAND string 501 in FIG. 5A is achieved by good electrical isolation between access devices and memory devices, when program pass voltages within the operating range are applied to the access devices. The resulting inversion channel in the access device reduces the electric field experienced by any charge stored in the associated memory device.). To achieve good program inhibit in the adjacent NAND string 502, good electrical interaction is needed between the access devices and the memory devices through capactive coupling between access devices and associated memory devices.

The read operation is discussed with reference to FIG. 5A. Suppose the memory cell to be read is the one in NAND string 501 with memory gate electrode word line WL(m)b. To read this cell, a small read voltage (e.g., between −2 volts to 4 volts) between the programmed threshold voltage and the erased threshold voltage is applied to word line WL(m)b. FIG. 9 more expressly shows a configuration of voltages imposed on the various terminals of a NAND-type memory string formed out of dual-gate devices during a read operation. As shown in FIG. 9, all access devices are rendered conducting by applying a suitable “on” voltage (e.g., 6 volts) at their gate electrodes, except the access device opposite the memory device being read, which is rendered non-conducting by applying a suitable “off” voltage (e.g., −3 volts) at its gate electrode. At the same time, all memory devices, other than the memory device being read, are turned off (e.g., by applying a −3 volts at their gate electrode) or put in an indeterminate conducting state.

During the read operation, because the access devices are conducting, inversion layers rich in electrons are formed in their channel regions, which shield the electric fields created by their gates electrodes. Consequently, little disturb of the charge stored in the corresponding memory devices result. However, for the memory device being read, as the associated access device is turned off, the voltage applied at its gate electrode (e.g., −3 volts) may reach through to the memory device. As discussed above, the electrical interaction is characterized by the sensitivity parameter. A sufficiently large negative voltage (i.e., relative to the gate voltage of the memory device) may result in memory charge disturb. As shown in FIG. 2, a small value for the sensitivity parameter (e.g., 0.1) may be achieved, so that the impact on the threshold voltage of the memory device by the voltage on the gate electrode of the access device may be made insignificant. In the example of FIGS. 1 and 2, a −3 volts on the gate electrode of the access device results in a −0.3 volts shift in the threshold voltage of the memory device (i.e., the voltage shift equals gate voltage of the access device multiplied by the sensitivity parameter). This small voltage shift is due to a small but non-zero electric field penetration from the access gate to the memory gate and is insufficient to disturb the charge stored in the memory device significantly. Indeed, there is room for the sensitivity parameter to increase before any disturb effect is seen.

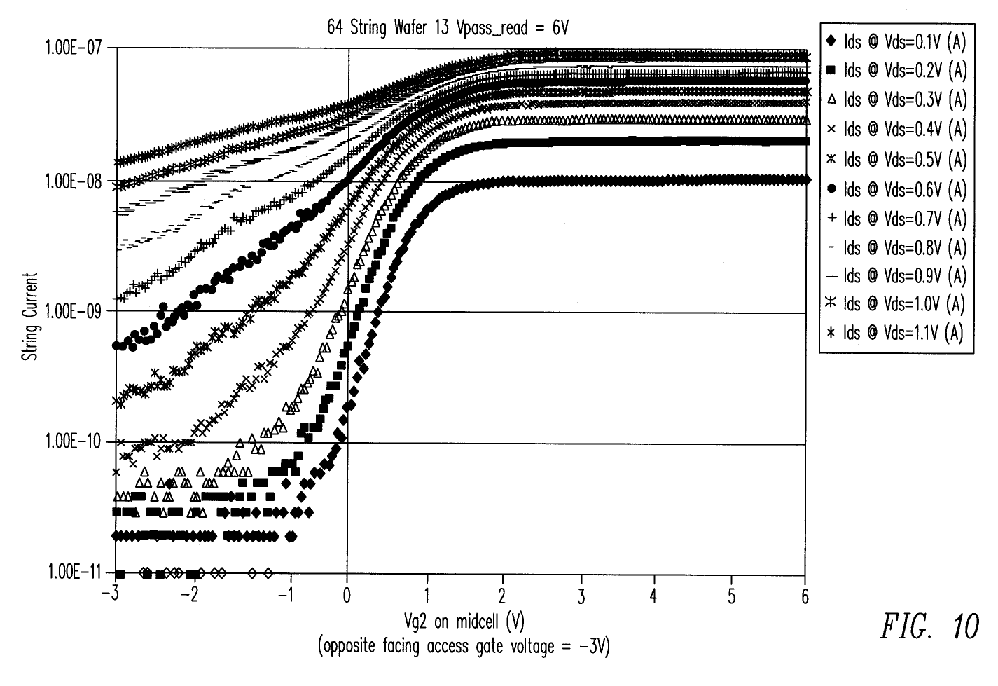

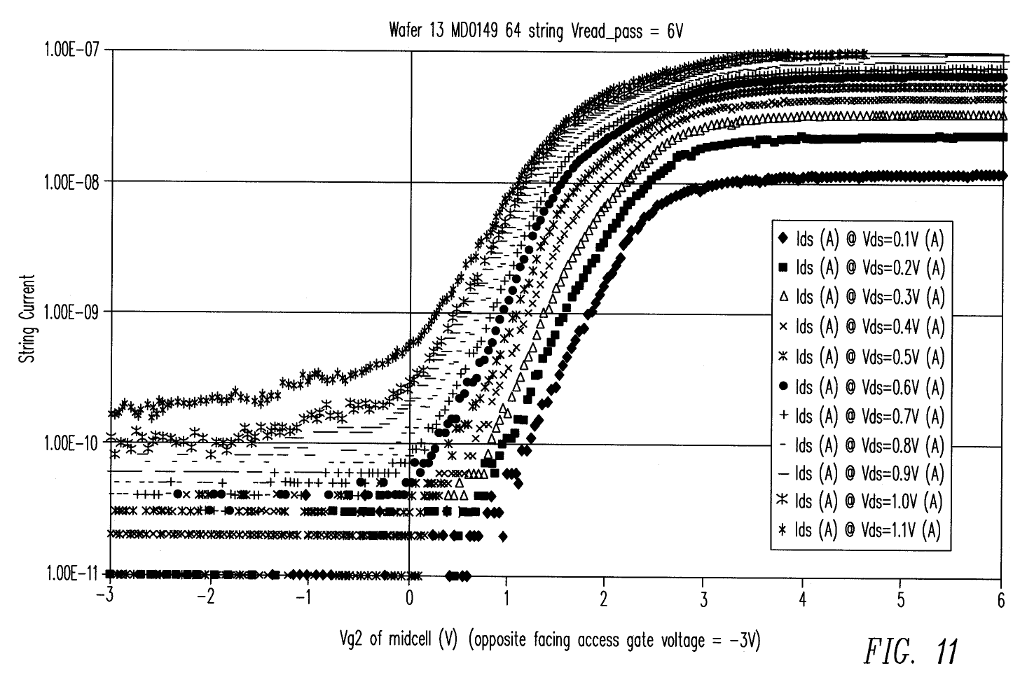

In a NAND-type memory string, the string current during a read operation should not exhibit “punchthrough” as the drain-source voltage is raised. FIG. 10 plots the current of a dual-gate memory string (e.g., the NAND-type memory string of FIG. 9) as a function of the voltage on the gate electrode of a memory device being read, for voltages between 0.1 volts to 1.1 volts across the memory string. FIG. 10 shows a punchthrough phenomenon, as the drain-source voltage increases from 0.1 volts to 1.1 volts. The punchthrough phenomenon is seen as the flatter rise in the string current for the higher source-drain voltages. Such flatter current characteristics make it more difficult to distinguish by the string current whether the memory device is programmed or erased. An error in reading the memory device may therefore result.

FIG. 11 plots the current of an improved memory string as a function of the voltage on the gate electrode of a memory device being read, for voltages between 0.1 volts to 1.1 volts across the memory string. The more desirable punchthrough characteristics may be achieved by reducing the thickness of the channel semiconductor. As the devices shrink in more advanced technology generations, the control of this punchthrough becomes even more rewarding. This enhanced scalability results in an increased sensitivity parameter. However, because of the relatively small sensitivity parameter, there is sufficient margin to allow such enhanced scalability to take place.

The suitable voltages for practicing the present invention may be determined empirically. At the same time, a small voltage (e.g., between 0.5 volts and 4 volts; preferably, 1 volt) is applied to bit line contact “Bit1” of NAND string 501. Common source line “CSL” of NAND string 501 is held at a lower voltage (e.g., ground voltage) than bit line contact “Bit1.” All access gate electrode word lines between bit line contact Bit1 and source CSL, except for word line WL(m)a, but including those of the select devices SG1a and SG2a, are applied a read pass voltage that is usually higher than the read voltage, but lower than the previously discussed program pass voltage. The read pass voltage may be provided between 1 volt and 8 volts, and typically, 4 volts, for example. All other memory cell gate electrode word lines may be tied to a voltage between 0 volts to −8 volts or left floating. The requirement for a reasonable electrical isolation during programming of a NAND string having a node in the active semiconductor layer applied a particular voltage results also in the lower read pass voltage applied having an even lesser effect on the stored charge in the associated memory devices in NAND string 501.

During the read operation, bit line contact “Bit2” of NAND string 502 in FIG. 5A can be left electrically floating or can be tied to a voltage close to ground voltage. Under either approach, read pass disturb in the NAND string being read is minimized. Also, read disturb and read pass disturb in adjacent NAND strings sharing the same word lines can also be minimized.

The erase operation is next discussed with reference to FIG. 5A. Erase is usually carried out using one of two methods, with many NAND strings being erased at the same time. The first erase method requires applying the ground voltage or a negative voltage to all the memory cell word lines in the memory block of NAND strings and may include applying the ground or negative voltage to the select devices of FIG. 5A. At the same time, a large positive voltage may be applied to all the bit line contacts and sources. As shown in FIG. 5A, the bit line contacts and source line contacts are “Bit1”, “Bit2” and “CSL” respectively. The voltage on these nodes may be between 7 volts and 15 volts. In this way, electric charge can tunnel out of the memory devices.

The second erase method also requires applying the ground voltage or a negative voltage to all the memory cell word lines in the memory block of NAND strings and may include the select devices. At the same time, a large positive voltage (e.g., between 7 to 20 volts) may be applied to all the access gate electrode word lines in the same block of NAND strings, while the bit line contacts and source regions all electrically float. Strong electrical interaction between the access devices and the memory devices ensures charge tunneling from the memory devices and allows erase to take place.

Based on the teachings above, very high density semiconductor devices may be formed by repetitive structures of the dual-gate devices discussed above, as illustrated by structure 800 in FIG. 6. FIGS. 7 and 8 show additional dual-gate device structures that are stacked in a repetitive manner to achieve high circuit densities. Specifically, FIG. 7 shows structure 900 which includes charge storing gate dielectric layers 108 on both sides of gate electrode layer 109 (i.e., using the same gate electrode to control more than one memory device). FIG. 8 shows structure 1000 which includes non-charge storing gate dielectric layers 106 on both sides of gate electrode layer 102 (i.e., using the same gate electrode to control more than one access device).

The above detailed description is provided to illustrate the specific embodiments of the present invention disclosed herein and is not intended to be limiting. Numerous variations and modifications of the present invention are possible within the scope of the present invention. The present invention is set forth in the accompanying claims.

I claim:

1. A dual-gate memory cell, comprising:
a memory device having a channel region provided on a first surface of a semiconductor layer; and
an access device having a channel region provided on a second surface of the semiconductor layer wherein a thickness of the channel region is provided such that electrical interaction between the access device and the memory device is characterized by a sensitivity parameter having a value within a predetermined range.

2. A dual-gate memory cell as in claim 1, wherein the semiconductor layer comprises polycrystalline semiconductor material.

3. A dual-gate memory cell as in claim 1, wherein the polycrystalline semiconductor material is selected from the group consisting of polycrystalline silicon, polycrystalline germanium, and a combination of polycrystalline silicon and polycrystalline germanium.

4. A dual-gate memory cell as in claim 1, wherein the memory device comprises a non-volatile memory device.

5. A dual-gate memory cell as in claim 4, wherein the memory device having a composite dielectric layer comprising silicon oxide and silicon nitride materials.

6. A dual-gate memory cell as in claim 5, wherein the silicon nitride material is selected from the group consisting of silicon nitride, silicon oxynitride, a silicon-rich silicon nitride and a silicon nitride having spatial variation of the silicon and oxygen contents.

7. A dual-gate memory cell as in claim 4, wherein the memory device comprises a floating conductor.

8. A dual-gate memory cell as in claim 7, wherein the floating conductor comprises nano-crystals placed between a gate electrode and the semiconductor layer.

9. A dual-gate memory cell as in claim 8, wherein the nano-crystals comprises a material selected from the group consisting of silicon, germanium, tungsten, and tungsten nitride.

10. A dual-gate memory cell as in claim 1, wherein the dual-gate memory cell is formed on an insulator.

11. A dual-gate memory cell as in claim 1, wherein the predetermined range is between 0.01 to 0.8.

12. A dual-gate memory cell as in claim 1, wherein a greater thickness of the channel region corresponds to a lesser value for the sensitivity parameter.

13. A memory circuit comprising a NAND-type memory string, the NAND-type memory string comprising:
a bit line contact;
a source contact;
a plurality of dual-gate memory cells serially connected by source/drain regions, wherein (a) a first source/drain region at one end of the serially connected dual-gate memory cells is selectably, electrically coupled to the bit line contact and a second source/drain region at another end of the serially connected dual-gate memory cells is selectably, electrically coupled to source contact, and wherein (b) the dual-gate memory cells each comprise:
a memory device having a channel region provided on a first surface of a semiconductor layer; and
an access device having a channel region provided on a second surface of the semiconductor layer wherein a thickness of the channel region is provided such that electrical interaction between the access device and the memory device is characterized by a sensitivity parameter having a value within a predetermined range.

14. A memory circuit as in claim 13 wherein the bit line contact and the first source/drain region are coupled through a select device;

15. A memory circuit as in claim 14, wherein the source contact and the second source/drain region are coupled through a select device.

16. A memory circuit as in claim 13 wherein, when the second surface of the semiconductor layer is allowed to electrically float, electrical interaction exists between the access device and the memory device to inhibit programming of the memory device.

17. A memory circuit as in claim 13, wherein, when programming one of the dual-gate memory cells, a first inversion channel region is formed in the channel region of the memory device of the dual-gate memory cells, and a second inversion channel is formed in an access device between the bit line contact and the dual-gate memory cell to be programmed, the first inversion channel being electrically connected to a predetermined voltage through the second inversion channel.

18. A memory circuit as in claim 13, wherein, when reading one of the dual-gate memory cells, an inversion channel region is formed in the channel region of an access device between the bit line contact and the dual-gate memory cell to be read, and wherein one of the source/drain regions adjacent the dual-gate memory cell to be read is electrically connected to a predetermined voltage through the inversion channel.

19. A memory circuit as in claim 13, further comprises a second NAND-type memory string substantially the same as the first NAND-type memory string, wherein corresponding gate electrodes of the memory devices in the first and second NAND-type memory strings are connected by a word line.

20. A memory circuit as in claim 19, wherein corresponding gate electrodes of the access devices in the first and second NAND-type memory strings are connected by a word line.

21. A memory circuit as in claim 19, wherein when programming a dual-gate memory cell in the first NAND-type memory string, a first predetermined voltage is applied to the bit line contact of the first NAND-type memory string, a voltage within the predetermined range of voltages is applied to the word lines connecting to access devices between the bit line contact and the dual-gate memory cell.

22. A memory circuit as in claim 21, wherein the word line connecting the corresponding gate electrodes of memory devices in the first and second NAND-type memory strings are applied a programming voltage, such that an inversion region is formed in the channel region of the memory device of the second NAND-type memory string, the inversion region being rendered electrically floating.

23. A memory circuit as in claim 21, wherein the source/drain regions in the second NAND-type memory string that are adjacent the dual-gate devices corresponding to dual gate memory cells between the bit line contact and the dual-gate memory cell in the first NAND-type memory string are allowed to electrically float.

24. A memory circuit as in claim 21, wherein when programming a dual-gate memory cell in the first NAND-type memory string, the bit line contact of the second NAND-type memory string is allowed to electrically float.

25. A memory circuit as in claim 21, wherein when programming a dual-gate memory cell in the first NAND-type memory string, the bit line contact of the second NAND-type memory string is connected to a predetermined voltage.

26. A memory circuit as in claim 21, wherein when programming a dual-gate memory cell in the first NAND-type memory string, the bit line contact of the first NAND-type memory string is applied a voltage within a predetermined range of voltages.

27. A memory circuit as in claim 13, wherein the dual-gate memory cells are fabricated on an insulator provided over a substrate.

28. A memory circuit as in claim 27, wherein the substrate comprises control circuits for controlling the NAND-type memory string.

29. A memory circuit as in claim 13, wherein the semiconductor layer comprises polycrystalline semiconductor material.

30. A memory circuit as in claim 29, wherein the polycrystalline semiconductor material is selected from the group consisting of polycrystalline silicon, polycrystalline germanium, and a combination of polycrystalline silicon and polycrystalline germanium.

31. A memory circuit as in claim 13, wherein the predetermined range is between 0.01 and 0.8.

32. A memory circuit as in claim 13, wherein a greater thickness in the channel region corresponds to a lesser value in the sensitivity parameter.

33. A method for fabricating a dual-gate memory cell, comprising:
forming a first conductor in an insulator layer;
forming a trench in the insulator layer, the bottom of the trench exposing the conductor;
providing a first dielectric layer adjacent the exposed conductor;
providing a semiconductor layer on the first dielectric layer;
providing a second dielectric layer over the semiconductor layer; and
providing a second conductor adjacent the second dielectric layer; and
wherein one of the first and second dielectric layers is charge-storing and the other of the first and second dielectric layers is non-charge storing, and wherein the semiconductor layer is provided a thickness such that electrical interaction between the access device and the memory device is characterized by a sensitivity parameter having a value within a predetermined range.

34. A method as in claim 33, further comprising providing source/drain regions in the semiconductor layer and wherein when a voltage is applied to the conductor layer adjacent the non-charge storing dielectric layer and the source/drain regions are allowed to float, the conductor layer adjacent the non-charge storing dielectric electrically interacts with the charge in the charge-storing dielectric layer.

35. A method as in claim 33, wherein the semiconductor layer comprises polycrystalline semiconductor material.

36. A method in claim 35, wherein the polycrystalline semiconductor material is selected from the group consisting of polycrystalline silicon, polycrystalline germanium, and a combination of polycrystalline silicon and polycrystalline germanium.

37. A method as in claim 33, wherein the charge-storing dielectric layer comprises silicon oxide and silicon nitride materials.

38. A method as in claim 37, wherein the silicon nitride material is selected from the group consisting of silicon nitride, silicon oxynitride, a silicon-rich silicon nitride and a silicon nitride having spatial variation of the silicon and oxygen contents.

39. A method as in claim 38, wherein the charge-storing dielectric layer comprises a floating conductor.

40. A method as in claim 39, wherein the floating conductor comprises nano-crystals placed between a gate electrode and the semiconductor layer.

41. A method in claim 40, wherein the nano-crystals comprises a material selected from the group consisting of silicon, germanium, tungsten, and tungsten nitride.

42. A method as in claim 33, further comprising connecting the semiconductor layer to a predetermined voltage when the voltage selected from a predetermined range of voltages is applied.

43. A method as in claim 33, wherein the sensitivity parameter is between 0.01 and 0.8.

44. A method as in claim 33, wherein a greater thickness in the channel region corresponds to a lesser value in the sensitivity parameter.

45. A memory circuit comprising a NAND-type memory string, the NAND-type memory string comprising:
a bit line contact;
a source contact;
a plurality of dual-gate memory cells serially connected by source/drain regions, wherein (a) a first source/drain region at one end of the serially connected dual-gate memory cells is selectably, electrically coupled to the bit line contact and a second source/drain region at another end of the serially connected dual-gate memory cells is selectably, electrically coupled to source contact, and wherein (b) the dual-gate memory cells each comprise:
a memory device having a channel region provided on a first surface of a semiconductor layer; and
an access device having a channel region provided on a second surface of the semiconductor layer wherein a thickness of the channel region is provided such that electrical interaction between the access device and the memory device is characterized by a sensitivity parameter having a value within a predetermined range.
